(19) United States
(12) Patent Application Publication
(10) Pub. No.: US 2026/0074697 A1
(43) Pub. Date: Mar. 12, 2026

(54) MAIN CONTROL DEVICE CAPABLE OF ENHANCING RECEPTION CAPACITY OF CODING CONFIGURATION SIGNALS

(71) Applicant: Xiamen PVTECH Co., Ltd., Xiamen (CN)

(72) Inventors: CHENGQUAN XU, Xiamen (CN); FUXING LU, Xiamen (CN)

(21) Appl. No.: 19/324,161

(22) Filed: Sep. 10, 2025

(30) Foreign Application Priority Data
Sep. 10, 2024 (CN) 202411264766.0

(51) Int. Cl. H03K 19/0175; H04L 1/00

(52) U.S. Cl. CPC H03K 19/017545; H03K 19/017509; H03K 19/017581; H04L 1/0009

(57) ABSTRACT

The main control device comprises a processing module with a switching pin and a plurality of signal pins, a first DIP switch, a second DIP switch, an inverting module, and a first switch and a second switch. The first DIP switch and second DIP switch are respectively connected to the signal pins through first and second signal switches. One end of the inverting module is connected to the processing module. The first switch connects to the first signal switches, the switching pin, the inverting module, and the operating voltage source. The second switch is connected to the second signal switches, the inverting module, and the operating voltage source.

### TECHNICAL FIELD

The disclosure relates to a main control device, in particular to a main control device capable of enhancing reception capacity of coding configuration signals.

### BACKGROUND

With the advancement of technology, intelligent lighting systems have been continuously improved to optimize user experience. Among them, lighting systems with group control functions have been widely applied in garages, parking lots, or other buildings. When a lighting device within a group detects a moving object (such as a person or vehicle) and generates a sensing signal, this lighting device simultaneously wakes up and activates other lighting devices within the same group. However, the lighting devices of this group cannot simultaneously wake up and activate the lighting devices of an adjacent group.

Therefore, if the moving object moves to the boundary between this group and an adjacent group, the lighting devices of the adjacent group cannot be activated in time.

To solve the above problem, the lighting device at the end of the group needs to be included in the adjacent group as well. In this way, the end lighting device of the group needs to simultaneously obtain two group identifiers, which requires twice the number of signal pins (I/O pins) as before. However, the currently available Bluetooth™ modules or microcontrollers do not have sufficient signal pins. Although multitasking chips can solve the above problem, these chips also significantly increase the cost.

### SUMMARY

One embodiment of the disclosure provides a main control device capable of enhancing reception capacity of coding configuration signals, which includes a processing module, a first DIP switch, a second DIP switch, an inverting module, a first switch and a second switch. The processing module has a switching pin and a plurality of signal pins. The first DIP switch has a plurality of first signal switches respectively connected to the of signal pins. The second DIP switch has a plurality of second signal switches respectively connected to the signal pins. One end of the inverting module is connected to the processing module. The first terminal of the first switch is connected to the first signal switches. The second terminal of the first switch is connected to one end of the inverting module and the switching pin. The third terminal of the first switch is connected to an operating voltage source. The first terminal of the second switch is connected to the second signal switches. The second terminal of the second switch is connected to the other end of the inverting module. The third terminal of the second switch is connected to the operating voltage source.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF DRAWINGS

The disclosure will become more fully understood from the detailed description given herein below and the accompanying drawings which are given by way of illustration only, and thus are not limitative of the disclosure and wherein:

FIG. 1 is a circuit diagram of a main control device capable of enhancing reception capacity of coding configuration signals in accordance with one embodiment of the disclosure.

FIG. 2 is a first schematic view of an operating state of the main control device capable of enhancing reception capacity of coding configuration signals in accordance with one embodiment of the disclosure.

FIG. 3 is a second schematic view of the operating state of the main control device capable of enhancing reception capacity of coding configuration signals in accordance with one embodiment of the disclosure.

FIG. 4 is a flow chart of a control method of the main control device capable of enhancing reception capacity of coding configuration signals in accordance with one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

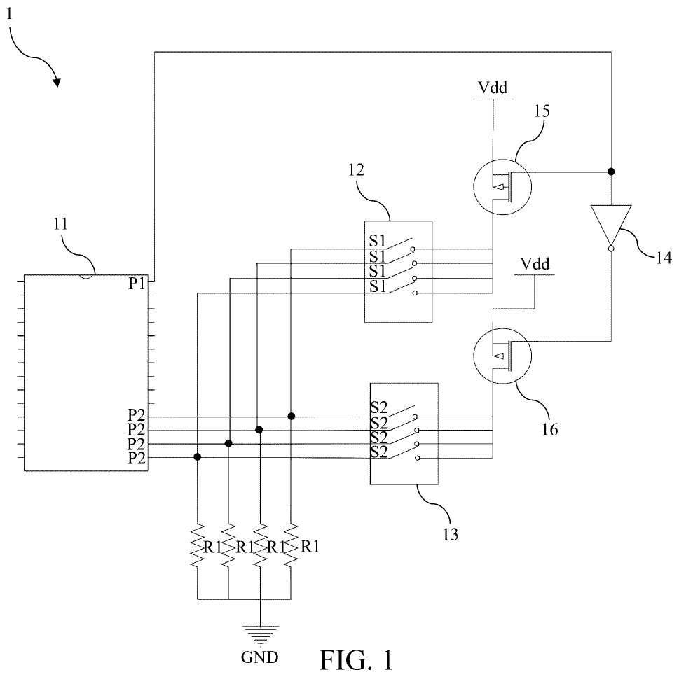

Please refer to FIG. 1, which is a circuit diagram of a main control device capable of enhancing reception capacity of coding configuration signals in accordance with one embodiment of the disclosure. As shown in FIG. 1, the main control device 1 includes a processing module 11, a first DIP (dual in-line package) switch 12, a second DIP switch 13, an inverting module 14, a first switch 15, and a second switch 16. The main control device 1 may serve as an intelligent device (such as an intelligent lighting device), a main control board of various electronic devices, or a part of the main control board of an intelligent device.

The processing module 11 includes a switching pin P1 and a plurality of signal pins P2. Each signal pin P2 is connected to a grounding point GND through a resistor R1. In one embodiment, the processing module 11 is a microcontroller (MCU). In another embodiment, the processing module 11 may be a Bluetooth™ module or other similar component. In yet another embodiment, the processing module 11 may be a central-processing unit (CPU), an application-specific integrated circuit (ASIC), a field programmable gate array (FPGA), or other similar component.

The first DIP switch 12 includes a plurality of first signal switches S1, and the first signal switches S1 are connected to the signal pins P2 respectively.

The second DIP switch 13 includes a plurality of second signal switches S2, and the second signal switches S2 are connected to the signal pins P2 respectively.

One end of the inverting module 14 is connected to the processing module 11. In one embodiment, the inverting module 14 is an inverter. In another embodiment, the inverting module 14 may also be another inverting circuit having similar functions.

The first terminal of the first switch 15 is connected to the first signal switches S1. The second terminal of the first switch 15 is connected to one end of the inverting module 14 and the switching pin P1. The third terminal of the first switch 15 is connected to an operating voltage source Vdd. In one embodiment, the first switch 15 is a metal-oxide-semiconductor field-effect transistor (MOSFET). The first terminal of the first switch 15 is the drain of the MOSFET; the second terminal is the gate of the MOSFET; the third terminal is the source of the MOSFET. In another embodiment, the first switch 15 may also be a bipolar junction transistor (BJT) or other similar component.

The first terminal of the second switch 16 is connected to the second signal switches S2. The second terminal of the second switch 16 is connected to the other end of the inverting module 14. The third terminal of the second switch 16 is connected to the operating voltage source Vdd. In one embodiment, the second switch 16 is a MOSFET. The first terminal of the second switch 16 is the drain of the MOSFET; the second terminal is the gate of the MOSFET; the third terminal is the source of the MOSFET. In another embodiment, the second switch 16 may also be a BJT or other similar component.

The embodiment just exemplifies the disclosure and is not intended to limit the scope of the disclosure; any equivalent modification and variation according to the spirit of the disclosure is to be also included within the scope of the following claims and their equivalents.

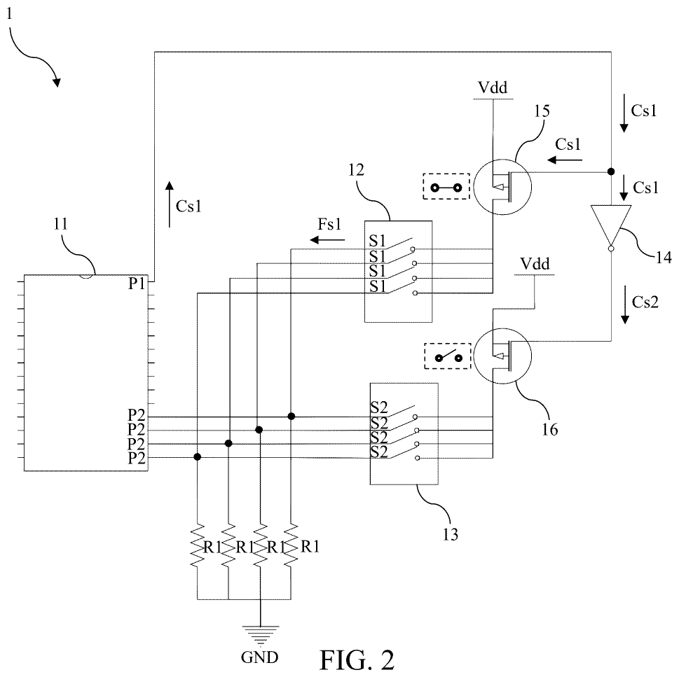

Please refer to FIG. 2, which is a first schematic view of an operating state of the in accordance with one embodiment of the disclosure. As shown in FIG. 2, the switching pin P1 of the processing module 11 transmits a first control signal Cs1 having a first level (high level) to the first switch 15 and the inverting module 14 to turn on the first switch 15 and activate the first DIP switch 12.

Then, the first control signal Cs1 is inverted by the inverting module 14 to generate a second control signal Cs2 having a second level (low level) opposite to the first level. The second control signal Cs2 is transmitted to the second switch 16 to turn off the second switch 16. Therefore, the second DIP switch 13 remains in the off state.

Finally, the processing module 11 reads the coding configuration signal Fs1 of the first DIP switch 12. The processing module 11 may read the coding configuration signal Fs1 of the first DIP switch 12 after generating the first control signal Cs1 and after a preset delay time. Since the first switch 15 and the second switch 16 require a certain period of time to reach the stable state after receiving control signals, the processing module 11 will read the coding configuration signal Fs1 only after the preset delay time to ensure accurate signal reading. For example, the coding configuration signal Fs1 may be a group identifier, light intensity, or the strength of various sensing signals.

The embodiment just exemplifies the disclosure and is not intended to limit the scope of the disclosure; any equivalent modification and variation according to the spirit of the disclosure is to be also included within the scope of the following claims and their equivalents.

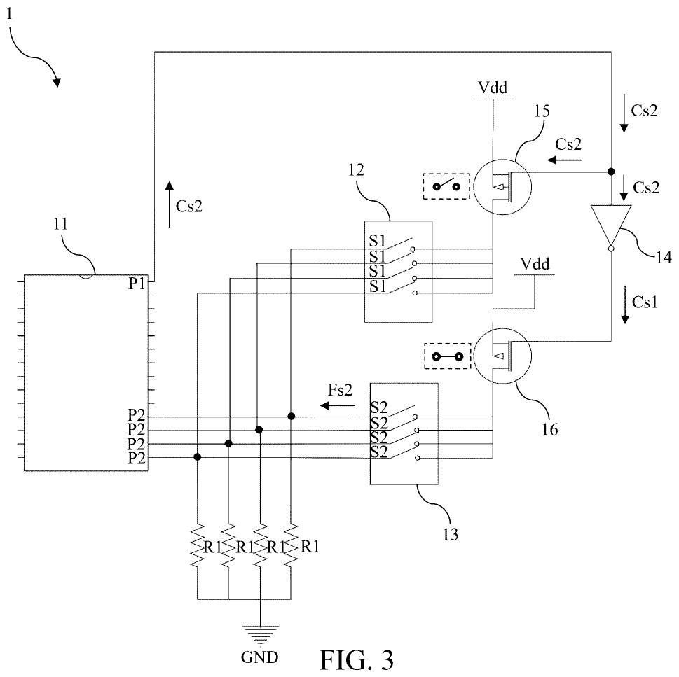

Please refer to FIG. 3, which is a second schematic view of the operating state of the in accordance with one embodiment of the disclosure. As shown in FIG. 3, the switching pin P1 of the processing module 11 transmits the second control signal Cs2 having the second level to the first switch 15 and the inverting module 14 to turn off the first switch 15. Therefore, the first DIP switch 12 remains in the off state.

Then, the second control signal Cs2 is inverted by the inverting module 14 to generate the first control signal Cs1 having the first level opposite to the second level. The first control signal Cs1 is transmitted to the second switch 16 to turn on the second switch 16 and activate the second DIP switch 13.

Finally, the processing module 11 reads the coding configuration signal Fs2 of the second DIP switch 13. Similarly, since the first switch 15 and the second switch 16 require a certain period of time to reach the stable state after receiving control signals, the processing module 11 will read the coding configuration signal Fs2 of the second DIP switch 13 only after the preset delay time to ensure accurate signal reading. For example, the coding configuration signal Fs2 may be a group identifier, light intensity, or the strength of various sensing signals.

The user may, depending on actual requirements, further increase the reception capacity of coding configuration signals by increasing the number of the switching pins P1 and/or the number of the signal pins P2 of the processing module 11 of the main control device 1. For example, in this embodiment, the processing module 11 has one switching pin P1 and four signal pins P2, thereby being able to receive eight-bit coding configuration signals (Fs1+Fs2). If the user adds one additional signal pin P2, the processing module 11 may receive ten-bit coding configuration signals (Fs1+Fs2). For example, in this embodiment, the processing module 11 has one switching pin P1 and four signal pins P2, thereby being able to receive eight-bit coding configuration signals (Fs1+Fs2). If the user adds one switching pin P1 and four signal pins P2, the processing module 11 may receive sixteen-bit coding configuration signals (Fs1+Fs2).

Through the above circuit structure and control mechanism, the main control device 1 can increase the reception capacity of coding configuration signals of the signal pins P2 up to twice the original capacity without requiring a multitasking chip, thereby achieving the effect of improving the reception capacity of coding configuration signals. Therefore, the cost of the main control device 1 can be reduced to meet actual requirements.

In addition, in this embodiment, the processing module 11 of the main control device 1 reads the coding configuration signal Fs1 of the first DIP switch 12 after generating the first control signal Cs1 and after a preset delay time. Similarly, the processing module 11 of the main control device 1 reads the coding configuration signal Fs2 of the second DIP switch 13 after generating the second control signal Cs2 and after a preset delay time. Since the first switch 15 and the second switch 16 require a certain period of time to reach a stable state after receiving control signals, the processing module 11 reads the coding configuration signals only after the preset delay time. The delay time mechanism ensures that the processing module 11 reads accurate coding configuration signals. Therefore, the performance of the main control device 1 can be significantly improved.

Moreover, in this embodiment, the user may further increase the reception capacity of coding configuration signals by adding the number of the switching pins P1 and/or the number of the signal pins P2 of the processing module 11 of the main control device 1. In this way, the main control device 1 may be applied to various intelligent applications and meet the requirements of these intelligent applications. Therefore, the main control device 1 can be more flexible in use and more comprehensive in application.

Furthermore, the main control device 1 has a circuit design capable of increasing the reception capacity of coding configuration signals and integrates a delay time mechanism, thereby significantly improving the overall performance of the main control device 1. Therefore, the main control device 1 can meet the requirements of various future applications in line with development trends. At the same time, since the circuit design of the main control device 1 is simple and integrates an effective control mechanism, the main control device 1 can achieve desired functionality without increasing or reducing costs. Therefore, the practicality of the main control device 1 can be significantly improved to meet the requirements of different intelligent applications.

The embodiment just exemplifies the disclosure and is not intended to limit the scope of the disclosure; any equivalent modification and variation according to the spirit of the disclosure is to be also included within the scope of the following claims and their equivalents.

It is worthy to point out that the currently available Bluetooth™ modules or microcontrollers do not have sufficient signal pins, so their reception capacity of coding configuration signals cannot be improved. By contrast, according to one embodiment of the present invention, the main control device 1 includes a processing module 11, a first DIP switch 12, a second DIP switch 13, an inverting module 14, a first switch 15 and a second switch 16. The processing module 11 has a switching pin P1 and a plurality of signal pins P2. The first DIP switch has a plurality of first signal switches S1 respectively connected to the of signal pins P2. The second DIP switch 13 has a plurality of second signal switches S2 respectively connected to the signal pins P2. One end of the inverting module 14 is connected to the processing module 11. The first terminal of the first switch 15 is connected to the first signal switches S1. The second terminal of the first switch 15 is connected to one end of the inverting module 14 and the switching pin P1. The third terminal of the first switch 15 is connected to an operating voltage source Vdd. The first terminal of the second switch 16 is connected to the second signal switches S2. The second terminal of the second switch 16 is connected to the other end of the inverting module 14. The third terminal of the second switch 16 is connected to the operating voltage source Vdd. The switching pin P1 of the processing module 11 transmits a first control signal Cs1 having a first level to the first switch 15 and the inverting module 14 so as to turn on the first switch 15 and activate the first DIP switch 12. The first control signal Cs1 is inverted by the inverting module 14 to generate a second control signal Cs2 having a second level opposite to the first level, and the second control signal Cs1 is transmitted to the second switch 16 to turn off the second switch 16, and the processing module 11 reads the coding configuration signal Fs1 of the first DIP switch 12. The switching pin P1 of the processing module 11 transmits the second control signal Cs2 having the second level to the first switch 15 and the inverting module 14 so as to turn off the first switch 15. The second control signal Cs2 is inverted by the inverting module 14 to generate the first control signal Cs1 having the first level opposite to the second level. The first control signal Cs1 is transmitted to the second switch 16 to turn on the second switch 16 and activate the second DIP switch 13, and the processing module 11 reads the coding configuration signal Fs2 of the second DIP switch 13. Through the above circuit structure and control mechanism, the main control device 1 can double the reception capacity of the coding configuration signal of the signal pins P2 without requiring a multitasking chip, thereby achieving the effect of enhancing the reception capacity of the coding configuration signal. Therefore, the cost of the main control device 1 can be reduced to meet actual requirements.

Also, according to an embodiment of the present invention, after generating the first control signal Cs1 and after a preset delay time, the processing module 11 of the main control device 1 reads the coding configuration signal Fs1 of the first DIP switch 12. Similarly, after generating the second control signal Cs2 and after the preset delay time, the processing module 11 of the main control device 1 reads the coding configuration signal Fs2 of the second DIP switch 13. Since the first switch 15 and the second switch 16 require a certain time to enter the stable state after receiving control signals, the processing module 11 reads the coding configuration signals only after the preset delay time has elapsed. The above delay time mechanism ensures that the processing module 11 can read the correct coding configuration signals. Therefore, the performance of the main control device 1 can be greatly improved.

In addition, according to an embodiment of the present invention, the user can further enhance the reception capacity of the coding configuration signals by increasing the number of the switching pins P1 and/or the signal pins P2 of the processing module 11 of the main control device 1. In this way, the main control device 1 can be applied to different intelligent applications and meet the requirements of such intelligent applications. Therefore, the main control device 1 can be more flexible in use and more comprehensive in application.

Furthermore, according to an embodiment of the present invention, the main control device 1 has a circuit design capable of enhancing the reception capacity of coding configuration signals, and integrates the delay time mechanism, thereby greatly improving the overall performance of the main control device 1. Therefore, the main control device 1 can meet the requirements of various future applications and conform to future development trends.

Moreover, according to an embodiment of the present invention, the circuit design of the main control device 1 is simple and integrates an effective control mechanism. In this way, the main control device 1 can achieve the desired effects without increasing or reducing the cost. Therefore, the practicality of the main control device 1 can be greatly enhanced to meet the requirements of different intelligent applications. As set forth above, the main control device capable of enhancing reception capacity of coding configuration signals can definitely achieve great technical effects.

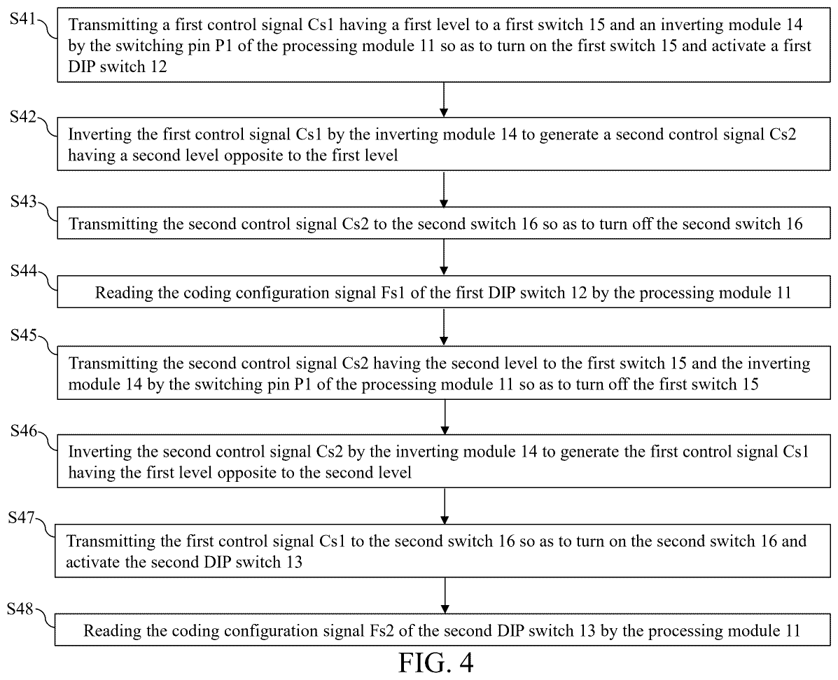

Please refer to FIG. 4, which is a flow chart of a control method of the main control device capable of enhancing reception capacity of coding configuration signals in accordance with one embodiment of the disclosure. As shown in FIG. 4, the control method of the embodiment includes the following steps:
Step S41: transmitting a first control signal Cs1 having a first level to a first switch 15 and an inverting module 14 by the switching pin P1 of the processing module 11 so as to turn on the first switch 15 and activate a first DIP switch 12.
Step S42: inverting the first control signal Cs1 by the inverting module 14 to generate a second control signal Cs2 having a second level opposite to the first level.
Step S43: transmitting the second control signal Cs2 to the second switch 16 so as to turn off the second switch 16.
Step S44: reading the coding configuration signal Fs1 of the first DIP switch 12 by the processing module 11.
Step S45: transmitting the second control signal Cs2 having the second level to the first switch 15 and the inverting module 14 by the switching pin P1 of the processing module 11 so as to turn off the first switch 15.
Step S46: inverting the second control signal Cs2 by the inverting module 14 to generate the first control signal Cs1 having the first level opposite to the second level.
Step S47: transmitting the first control signal Cs1 to the second switch 16 so as to turn on the second switch 16 and activate the second DIP switch 13.
Step S48: reading the coding configuration signal Fs2 of the second DIP switch 13 by the processing module 11.

The embodiment just exemplifies the disclosure and is not intended to limit the scope of the disclosure; any equivalent modification and variation according to the spirit of the disclosure is to be also included within the scope of the following claims and their equivalents.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

To sum up, according to one embodiment of the present invention, the main control device 1 includes a processing module 11, a first DIP switch 12, a second DIP switch 13, an inverting module 14, a first switch 15 and a second switch 16. The processing module 11 has a switching pin P1 and a plurality of signal pins P2. The first DIP switch has a plurality of first signal switches S1 respectively connected to the of signal pins P2. The second DIP switch 13 has a plurality of second signal switches S2 respectively connected to the signal pins P2. One end of the inverting module 14 is connected to the processing module 11. The first terminal of the first switch 15 is connected to the first signal switches S1. The second terminal of the first switch 15 is connected to one end of the inverting module 14 and the switching pin P1. The third terminal of the first switch 15 is connected to an operating voltage source Vdd. The first terminal of the second switch 16 is connected to the second signal switches S2. The second terminal of the second switch 16 is connected to the other end of the inverting module 14. The third terminal of the second switch 16 is connected to the operating voltage source Vdd. The switching pin P1 of the processing module 11 transmits a first control signal Cs1 having a first level to the first switch 15 and the inverting module 14 so as to turn on the first switch 15 and activate the first DIP switch 12. The first control signal Cs1 is inverted by the inverting module 14 to generate a second control signal Cs2 having a second level opposite to the first level, and the second control signal Cs1 is transmitted to the second switch 16 to turn off the second switch 16, and the processing module 11 reads the coding configuration signal Fs1 of the first DIP switch 12. The switching pin P1 of the processing module 11 transmits the second control signal Cs2 having the second level to the first switch 15 and the inverting module 14 so as to turn off the first switch 15. The second control signal Cs2 is inverted by the inverting module 14 to generate the first control signal Cs1 having the first level opposite to the second level. The first control signal Cs1 is transmitted to the second switch 16 to turn on the second switch 16 and activate the second DIP switch 13, and the processing module 11 reads the coding configuration signal Fs2 of the second DIP switch 13. Through the above circuit structure and control mechanism, the main control device 1 can double the reception capacity of the coding configuration signal of the signal pins P2 without requiring a multitasking chip, thereby achieving the effect of enhancing the reception capacity of the coding configuration signal. Therefore, the cost of the main control device 1 can be reduced to meet actual requirements.

Also, according to an embodiment of the present invention, after generating the first control signal Cs1 and after a preset delay time, the processing module 11 of the main control device 1 reads the coding configuration signal Fs1 of the first DIP switch 12. Similarly, after generating the second control signal Cs2 and after the preset delay time, the processing module 11 of the main control device 1 reads the coding configuration signal Fs2 of the second DIP switch 13. Since the first switch 15 and the second switch 16 require a certain time to enter the stable state after receiving control signals, the processing module 11 reads the coding configuration signals only after the preset delay time has elapsed. The above delay time mechanism ensures that the processing module 11 can read the correct coding configuration signals. Therefore, the performance of the main control device 1 can be greatly improved.

In addition, according to an embodiment of the present invention, the user can further enhance the reception capacity of the coding configuration signals by increasing the number of the switching pins P1 and/or the signal pins P2 of the processing module 11 of the main control device 1. In this way, the main control device 1 can be applied to different intelligent applications and meet the requirements of such intelligent applications. Therefore, the main control device 1 can be more flexible in use and more comprehensive in application.

Furthermore, according to an embodiment of the present invention, the main control device 1 has a circuit design capable of enhancing the reception capacity of coding configuration signals, and integrates the delay time mechanism, thereby greatly improving the overall performance of the main control device 1. Therefore, the main control device 1 can meet the requirements of various future applications and conform to future development trends.

Moreover, according to an embodiment of the present invention, the circuit design of the main control device 1 is simple and integrates an effective control mechanism. In this way, the main control device 1 can achieve the desired effects without increasing or reducing the cost. Therefore, the practicality of the main control device 1 can be greatly enhanced to meet the requirements of different intelligent applications.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is

1. A main control device capable of enhancing reception capacity of coding configuration signals, comprising:
a processing module having a switching pin and a plurality of signal pins;
a first DIP switch having a plurality of first signal switches respectively connected to the of signal pins;
a second DIP switch having a plurality of second signal switches respectively connected to the signal pins;
an inverting module, one end thereof being connected to the processing module;
a first switch, wherein a first terminal of the first switch is connected to the first signal switches, a second terminal of the first switch is connected to one end of the inverting module and the switching pin, and a third terminal of the first switch is connected to an operating voltage source; and
a second switch, wherein a first terminal of the second switch is connected to the second signal switches, a second terminal of the second switch is connected to another end of the inverting module, and a third terminal of the second switch is connected to the operating voltage source.

2. The main control device capable of enhancing reception capacity of coding configuration signals as claimed in claim 1, wherein the switching pin of the processing module is configured to transmit a first control signal having a first level to the first switch and the inverting module so as to turn on the first switch and activate the first DIP switch, wherein the first control signal is inverted by the inverting module to generate a second control signal having a second level opposite to the first level, and the second control signal is transmitted to the second switch to turn off the second switch, and the processing module is configured to read a coding configuration signal of the first DIP switch.

3. The main control device capable of enhancing reception capacity of coding configuration signals as claimed in claim 2, wherein the processing module is configured to read the coding configuration signal of the first DIP switch after the first control signal is generated and after a preset delay time has elapsed.

4. The main control device capable of enhancing reception capacity of coding configuration signals as claimed in claim 1, wherein the switching pin of the processing module is configured to transmit a second control signal having a second level to the first switch and the inverting module so as to turn off the first switch, wherein the second control signal is inverted by the inverting module to generate a first control signal having a first level opposite to the second level, the first control signal is transmitted to the second switch to turn on the second switch and activate the second DIP switch, and the processing module is configured to read a coding configuration signal of the second DIP switch.

5. The main control device capable of enhancing reception capacity of coding configuration signals as claimed in claim 4, wherein the processing module is configured to read the coding configuration signal of the second DIP switch after the second control signal is generated and after a preset delay time has elapsed.

6. The main control device capable of enhancing reception capacity of coding configuration signals as claimed in claim 1, wherein each of the signal pins is connected to a grounding point via a resistor.

7. The main control device capable of enhancing reception capacity of coding configuration signals as claimed in claim 1, wherein the first switch and the second switch are metal-oxide-semiconductor field-effect transistors or bipolar junction transistors.

8. The main control device capable of enhancing reception capacity of coding configuration signals as claimed in claim 1, wherein the inverting module is an inverter.

9. The main control device capable of enhancing reception capacity of coding configuration signals as claimed in claim 1, wherein the processing module is a microcontroller, a central-processing unit, an application-specific integrated circuit, or a field programmable gate array.

10. The main control device capable of enhancing reception capacity of coding configuration signals as claimed in claim 1, wherein the processing module is a Bluetooth™ module.
